(19) United States
(12) Patent Application Publication
(10) Pub. No.: US 2025/0174545 A1
(43) Pub. Date: May 29, 2025

(54) ELECTRONIC DEVICES AND METHODS OF MANUFACTURING ELECTRONIC DEVICES

(71) Applicant: Amkor Technology Singapore Holding Pte. Ltd., Singapore (SG)

(72) Inventors: Sang Hyun Jin, Incheon (KR); Ki Yeul Yang, Incheon (KR); Jin Suk Jeong, Incheon (KR)

(73) Assignee: Amkor Technology Singapore Holding Pte. Ltd., Singapore (SG)

(21) Appl. No.: 18/518,771

(22) Filed: Nov. 24, 2023

(51) Int. Cl. H01L 23/498; H01L 21/768; H01L 23/538

(52) U.S. Cl. CPC H01L 23/49866; H01L 21/76871; H01L 23/49816; H01L 23/5386

(57) ABSTRACT

In one example, an electronic device can comprise an electronic component, a component passivation layer coupled to the electronic component, and a component interconnect extending from the electronic component through the component passivation layer. A substrate can be coupled to the component passivation layer and the component interconnect. The substrate can include a substrate passivation layer coupled to the component passivation layer along a bond boundary, and the substrate passivation layer can comprise an inorganic material. A substrate inward terminal extends through the substrate passivation layer and can be coupled to the component interconnect along the bond boundary. A seed is between the substrate passivation layer and the substrate inward terminal. A dielectric structure can be coupled to the substrate passivation layer. A conductive structure extends through the dielectric structure and is coupled to the substrate inward terminal. Other examples and related methods are also disclosed herein.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, for example resulting in excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIG. 1A shows a detailed view of the example electronic device of FIG. 1.

FIGS. 2A to 2H show cross-sectional views of an example method for manufacturing an example electronic device.

FIG. 3 shows a cross-sectional view of an example electronic device.

FIGS. 4A to 4C show cross-sectional views of an example electronic device.

FIG. 5 shows a cross-sectional view of an example electronic device.

FIG. 5A shows a detailed view of the example electronic device of FIG. 5.

FIGS. 6A to 6H show an example method for manufacturing an example electronic device using cross-sectional views.

The following discussion provides various examples of electronic devices and methods of manufacturing electronic devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or.” As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” etc. may be used herein to describe various elements; however, the described elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly coupled by one or more other elements. For example, if element A is coupled to element B, then element A can be directly contacting element B or indirectly coupled to element B by an intervening element C. Similarly, the terms “over” or “on” may be used to describe two elements directly contacting each other or describe two elements indirectly coupled by one or more other elements. As used herein, the term “coupled” can refer to an electrical coupling or a mechanical coupling.

### DESCRIPTION

An example electronic device can comprise an electronic component, a component passivation layer coupled to the electronic component, and a component interconnect extending from the electronic component through the component passivation layer. A substrate can be coupled to the component passivation layer and the component interconnect. The substrate can include a substrate passivation layer coupled to the component passivation layer along a bond boundary, and the substrate passivation layer can comprise an inorganic material. A substrate inward terminal extends through the substrate passivation layer and can be coupled to the component interconnect along the bond boundary. A seed is between the substrate passivation layer and the substrate inward terminal. A dielectric structure can be coupled to the substrate passivation layer. A conductive structure extends through the dielectric structure and is coupled to the substrate inward terminal.

An example method of manufacturing an electronic device includes the steps of providing a substrate passivation layer defining an aperture and comprising an inorganic material, providing a seed over the substrate passivation layer and in the aperture, and providing a conductive structure over the seed and in the aperture. The conductive structure can include a substrate inward terminal. A dielectric structure can be provided over the seed and the substrate passivation layer. A portion of the seed can be removed to expose a side of the substrate inward terminal. The side of the substrate inward terminal can be recessed from a side of the substrate passivation layer by a dishing height. An electronic component can comprise a component passivation layer over the substrate passivation layer. The electronic component defines a void between the exposed side of the substrate inward terminal and a component interconnect of the electronic component. The substrate passivation layer can be coupled to the component passivation layer along a bond boundary. The substrate inward terminal can be bonded to the component interconnect along the bond boundary by applying a bonding temperature.

An example electronic device can include an electronic component comprising a component passivation layer coupled to the electronic component, and a component interconnect extending from the electronic component through the component passivation layer. A side of the component passivation layer and a side of the component interconnect can be located along a bond boundary. A substrate can be coupled to the electronic component. The substrate includes a substrate passivation layer coupled to the component passivation layer along the bond boundary. The substrate passivation layer comprises inner walls defining an aperture. A seed can be coupled to the inner walls of the substrate passivation layer. An interface layer is coupled to the component interconnect along the bond boundary and coupled to the seed. A barrier layer can be coupled to the interface layer with the interface layer between the seed and the barrier layer. A dielectric structure can be coupled to the substrate passivation layer. A conductive structure extends through the dielectric structure and into the aperture. The conductive structure is coupled to the barrier layer.

Other examples are included in the present disclosure. Such examples may be found in the figures, in the claims, or in the description of the present disclosure.

Various examples use bonding techniques with tightly controlled material thickness or height along bonding surfaces to compensate for mismatched coefficients of thermal expansion (CTE) between adjacent materials. In some examples, a metallic bonding surface can be recessed from an inorganic insulating surface by a predetermined dishing height. The dishing height can be tightly controlled using titanium (Ti) etching or other etching techniques to control the dishing height. Etching tends to leave smoother surfaces than chemical mechanical polishing (CMP) processes, which can leave behind particulate or surface imperfections. Some examples can include a gold (Au) and copper (Cu) alloy bonding interface. Various examples also include hybrid redistribution structures (e.g., having both inorganic and organic layers) with hybrid bonding interfaces. Hybrid bonding interfaces can be pad-less to improve (e.g., decrease) pitch.

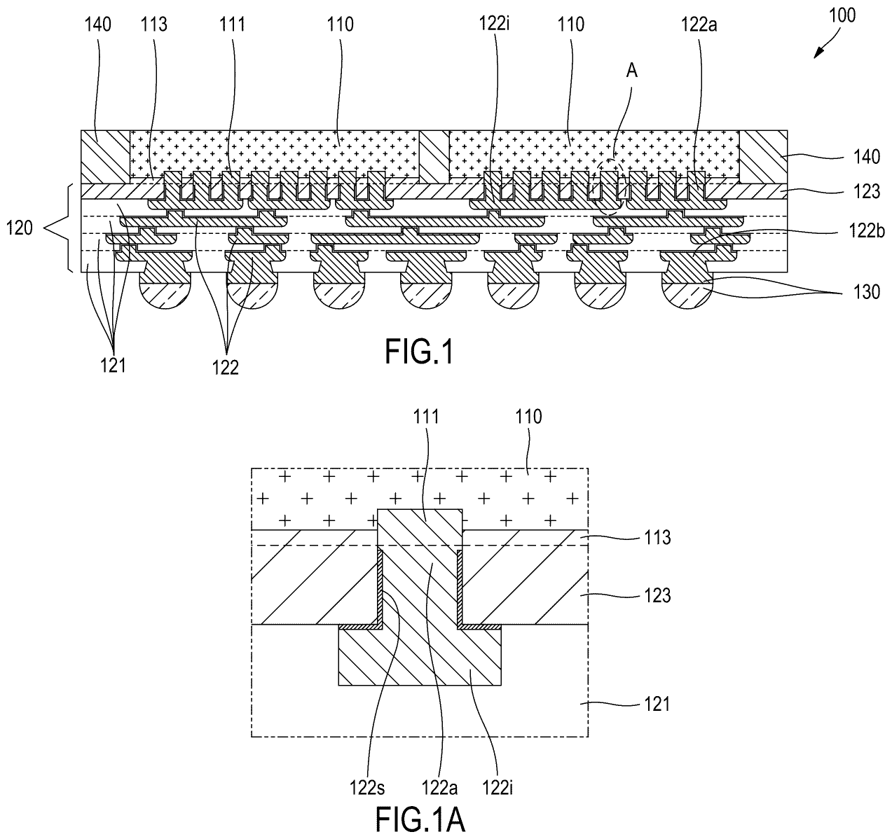

FIG. 1 shows a cross-sectional view of an example electronic device 100. FIG. 1A is an enlarged view of electronic device 100 from region A in FIG. 1. In the example shown in FIGS. 1 and 1A, electronic device 100 can comprise electronic component(s) 110, substrate 120, substrate interconnects 130, and encapsulant 140.

Electronic component 110 can comprise component interconnects 111 and component passivation layer 113. Substrate 120 can comprise dielectric structure 121, conductive structure 122, and substrate passivation 123. Conductive structure 122 can comprise substrate inward terminals 122a, seed 122s, inner conductive structure 122i, and substrate outward terminals 122b.

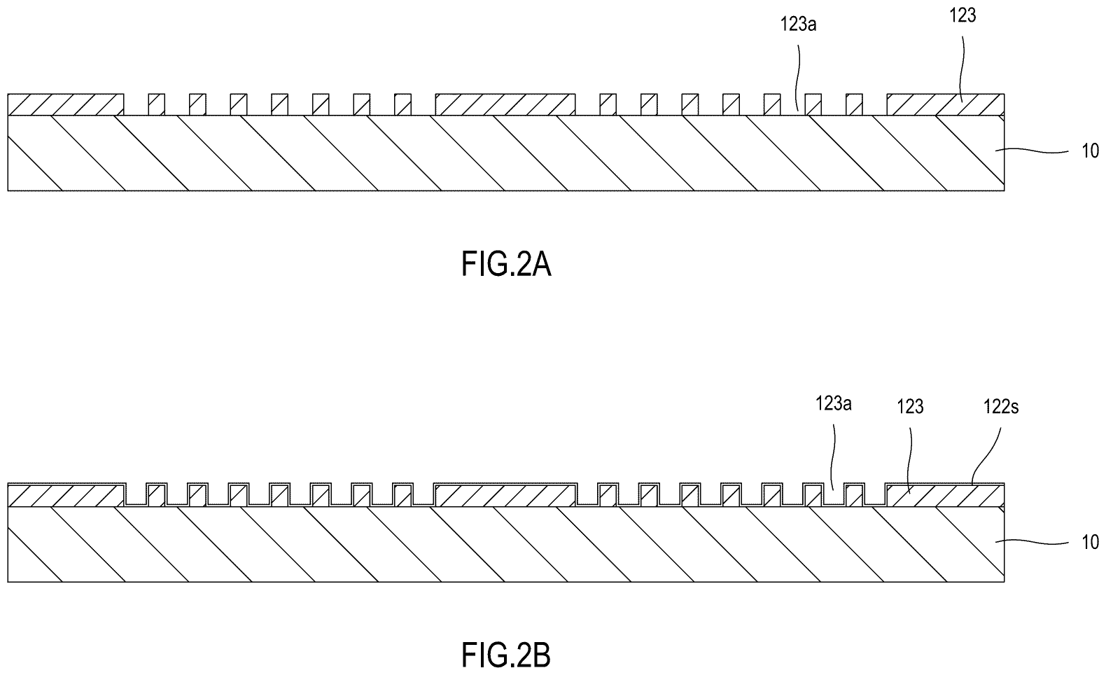

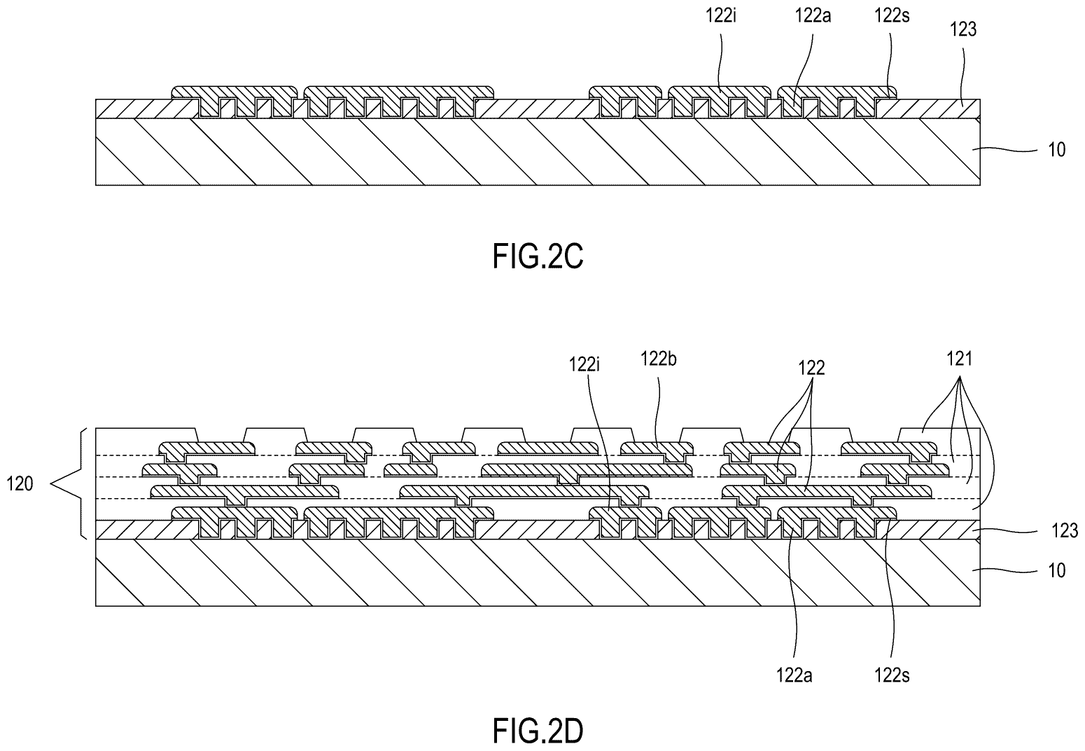

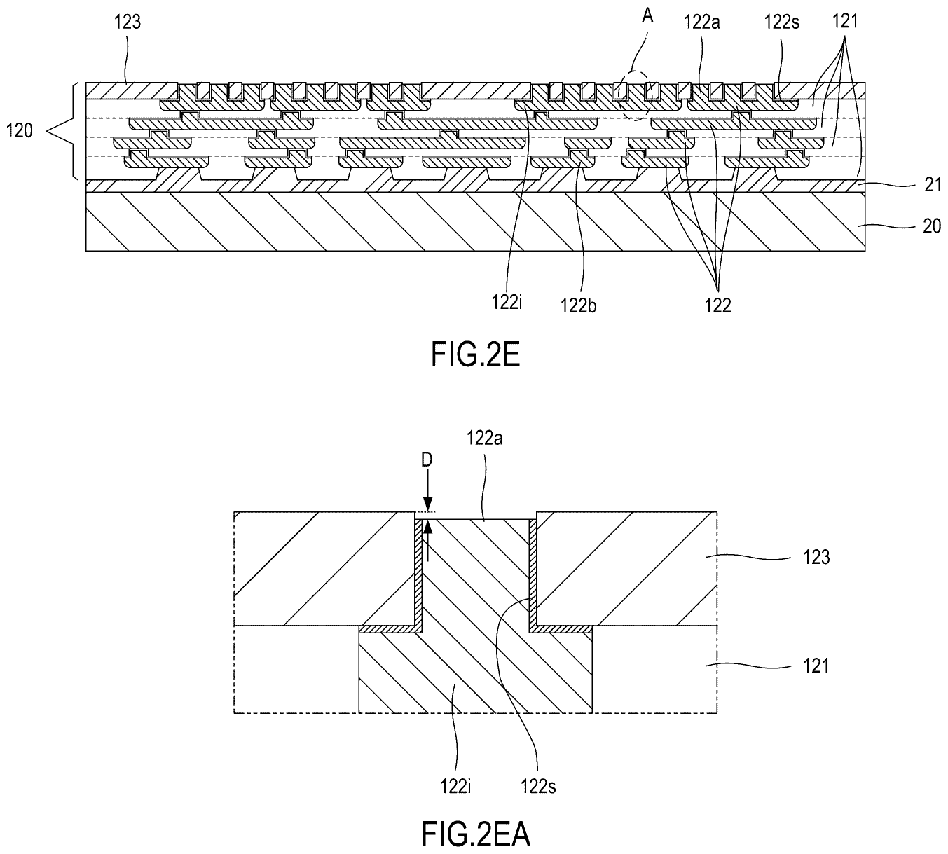

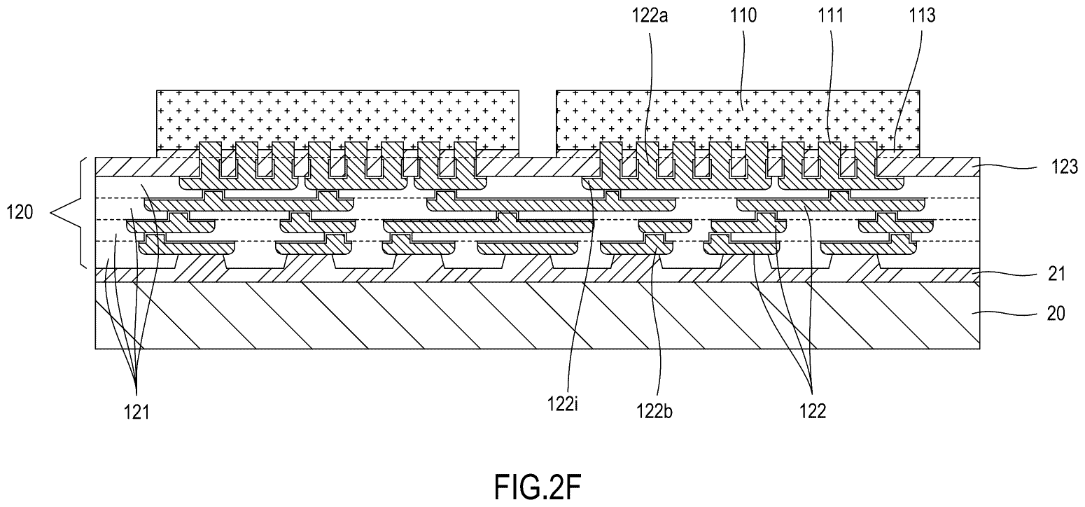

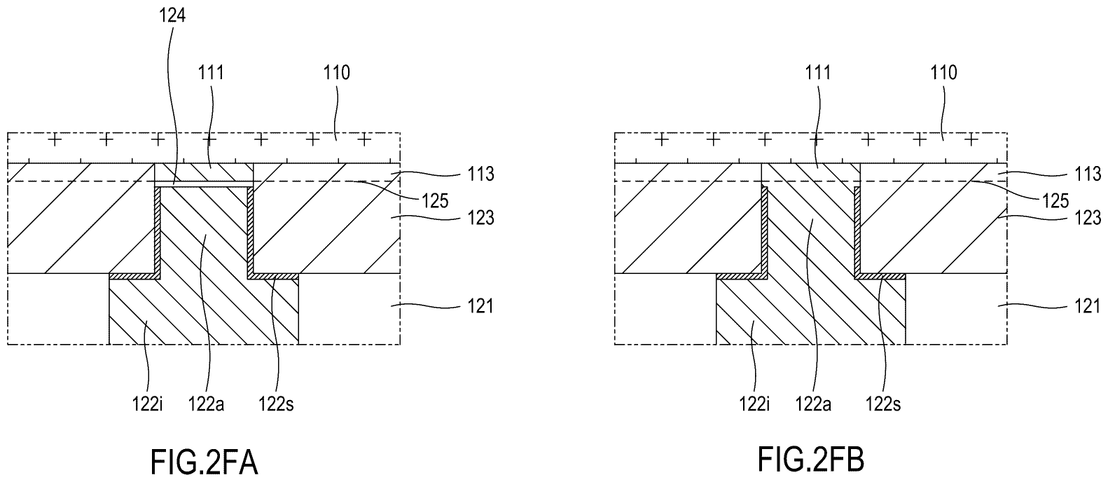

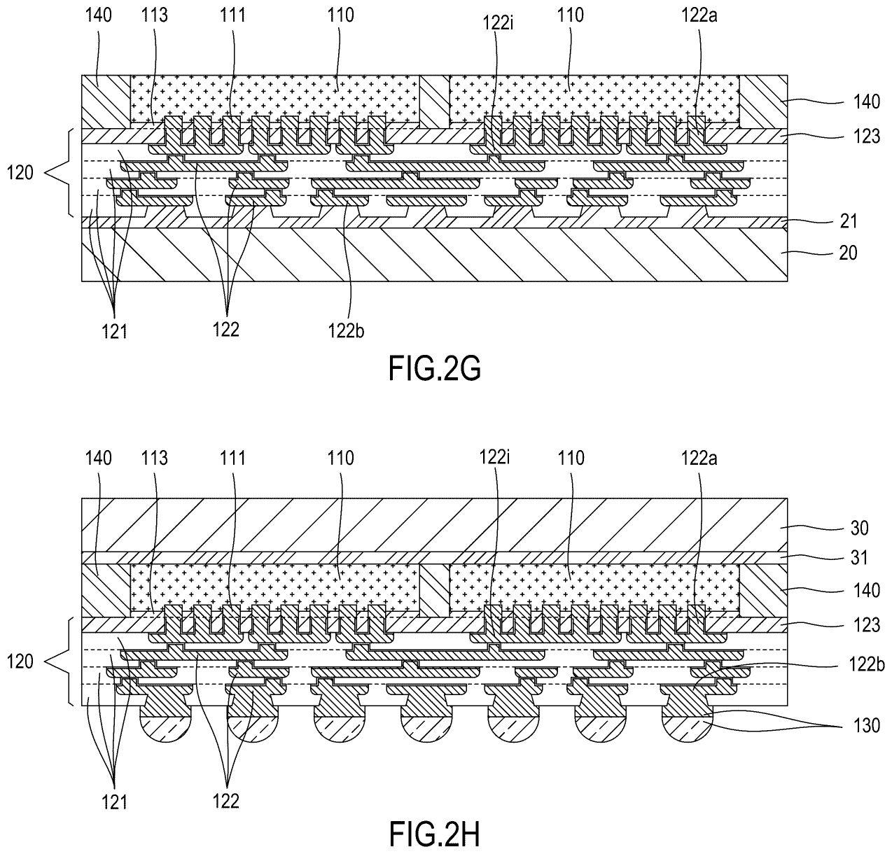

FIGS. 2A to 2H show cross-sectional views of an example method for manufacturing an example electronic device, such as electronic device 100.

FIG. 2A shows a cross-sectional view of electronic device 100 at an early stage of manufacture. In the example shown in FIG. 2A, substrate passivation 123 can be provided on the surface of carrier 10. Substrate passivation 123 can be provided to cover the entire surface of carrier 10 by deposition or coating. For example, substrate passivation 123 can be provided by deposition such as physical vapor deposition (PVD), chemical vapor deposition (CVD), metal organic chemical vapor deposition (MOCVD), atomic layer deposition (ALD), low pressure chemical vapor deposition (LPCVD), or plasma enhanced chemical vapor deposition (PECVD). For example, substrate passivation 123 can be provided by coating such as spin coating, spray coating, dip coating, or rod coating.

In some examples, substrate passivation 123 can comprise an inorganic material. For example, substrate passivation 123 can be silicon oxide (SiO2), silicon carbon nitride (SiCN), or silicon nitride (SiN). In some examples, the thickness of substrate passivation 123 can range from approximately 0.1 micrometers (μm) to 20 μm. As used herein to describe measurements of displacement, distance, or length, the term approximately can mean +/−5%, +/−10%, +/−15%, +/−20%, or +/−25%.

Carrier 10 can be a substantially planar plate. In some examples, carrier 10 can comprise or be referred to as a plate, a board, a wafer, a panel, or a strip. Carrier 10 can be made of metal, ceramic, or semiconductor material. In some examples, carrier 10 can be made of glass (e.g., soda-lime glass). The thickness of carrier 10 can range from approximately 300 μm to approximately 2000 μm, and the width of carrier 10 can range from approximately 100 millimeters (mm) to approximately 300 mm. Carrier 10 can enable handling and manufacturing of multiple devices during a process of providing substrate 120.

After a mask pattern is formed on a top side of substrate passivation 123, apertures 123a can be provided in substrate passivation 123 by removing portions of substrate passivation 123 exposed from the mask pattern through etching. Apertures 123a can be defined by inner walls of the substrate passivation layer 123. A top side of carrier 10 can be exposed through apertures 123a. In some examples, the mask pattern can comprise photo resist. The mask pattern can be removed after substrate passivation 123 is patterned.

FIG. 2B shows a cross-sectional view of electronic device 100 at a later stage of manufacture. In the example shown in FIG. 2B, seed 122s can be provided to cover substrate passivation 123 and carrier 10.

Seed 122s can be in contact with the top side of substrate passivation 123, sidewalls of apertures 123a, and the top side of carrier 10. In some examples, seed 122s can be provided by electroless plating, electrolytic plating, sputtering, PVD, CVD, MOCVD, ALD, LPCVD, or PECVD. In some examples, seed 122s can be referred to as or comprise a conductive layer, a seed layer, or a buffer layer. In some examples, seed 122s can comprise Ti, TiW, W, Cr, Al, Ni, Au, Ag, or Cu. In some examples, the thickness of seed 122s can range from approximately 0.01 μm to 0.1 μm, 0.01 μm to 0.05 μm, or 0.01 μm to 0.03 μm.

FIG. 2C shows a cross-sectional view of electronic device 100 at a later stage of manufacture. In the example shown in FIG. 2C, inner conductive structure 122i can be provided over seed 122s.

Inner conductive structure 122i can be provided in patterns, and the patterns can be in contact with and electrically coupled to seed 122s. Inner conductive structure 122i can comprise one or more layers defining signal distribution elements. Inner conductive structure 122i can comprise or be referred to as conductive paths, conductive layers, traces, pads, vias, redistribution layer (RDL), wiring patterns, under bump metallization (UBM), or circuit patterns In some examples, inner conductive structure 122i can comprise copper (Cu), aluminum (Al), nickel (Ni), palladium (Pd), titanium (Ti), tungsten (W), titanium/tungsten, gold (Au), silver (Ag), an alloy, or other suitably conductive material as known to one of ordinary skill in the art. Inner conductive structure 122i can be provided by electroless plating, electrolytic plating, sputtering, PVD, CVD, MOCVD, ALD, LPCVD, or PECVD. In some examples, inner conductive structure 122i can be provided by forming a mask pattern (e.g., a photo resist) covering portions of the upper side of seed 122s and then plating inner conductive structure 122i using seed 122s as a seed layer. After forming inner conductive structure 122i, the mask pattern can be removed.

In accordance with various examples, after forming inner conductive structure 122i, the portions of seed 122s that are not covered by inner conductive structure 122i can be removed. In some examples, the portions of seed 122s exposed from inner conductive structure 122i can be removed by etching. As seed 122s is removed, substrate passivation 123 can be exposed. Seed 122s can have multiple patterns, like conductive structure 122, and can be included in inner conductive structure 122i. In accordance with various examples, inner conductive structure 122i can comprise substrate inward terminals 122a and traces extending along the top side of substrate passivation 123 (e.g., along the side of substrate passivation 123 that is opposite electronic components 110 in FIG. 1). Substrate inward terminals 122a can fill the interior of apertures 123a. The thickness of inner conductive structure 122i can range from approximately 0.5 μm to approximately 50 μm.

FIG. 2D shows a cross-sectional view of electronic device 100 at a later stage of manufacture. In the example shown in FIG. 2D, dielectric structure 121 and conductive structure 122 can be provided in alternating layers over inner conductive structure 122i and substrate passivation 123.

In accordance with various examples, dielectric structure 121 can comprise or be referred to as one or more dielectrics, dielectric materials, dielectric layers, passivation layers, insulating layers, or protective layers. In some examples, dielectric structure 121 can comprise organic dielectric materials. For example, dielectric structure 121 can comprise an electrically insulating material such as polymer, polyimide (PI), benzocyclobutene (BCB), polybenzoxazole (PBO), bismaleimide triazine (BT), Ajinomoto Buildup Film (ABF), a molding material, a phenolic resin, an epoxy, silicone, or an acrylate polymer. In some examples, dielectric structure 121 can be provided by spin coating, spray coating, dip coating, rod coating, printing, oxidation, PVD, CVD, MOCVD, ALD, LPCVD, PECVD, or other processes as known to one of ordinary skill in the art. Dielectric structure 121 can maintain the shape of substrate 120 and can also structurally support conductive structure 122 and electronic components 110 (FIG. 1). Dielectric structure 121 can be in contact with conductive structure 122. Dielectric structure 121 can expose portions of conductive structure 122. For example, substrate outward terminals 122b can be exposed from a distal side of dielectric structure 121 (e.g., from a side opposite or distal to substrate passivation 123). In some examples, the thicknesses of individual layers of dielectric structure 121 can range from about 3 μm to about 100 μm.

In accordance with various embodiments, conductive structure 122 can comprise or be referred to as one or more conductors, conductive materials, conductive paths, conductive layers, RDLs, wiring layers, signal distribution elements, traces, vias, pads, or UBM. In some examples, one or more of the conductive layers can be interleaved with dielectric layers of dielectric structure 121. In some examples, conductive structure 122 can comprise Cu, Al, Ni, Pd, Ti, W, Ti/W, Au, Ag, an alloy, or other suitably conductive material as known to one of ordinary skill in the art. In some examples, conductive structure 122 can be provided by sputtering, electroless plating, electrolytic plating, PVD, CVD, MOCVD, ALD, LPCVD, PECVD, or other processes as known to one of ordinary skill in the art.

In accordance with various examples, conductive structure 122 can comprise substrate inward terminals 122a, inner conductive structure 122i, and substrate outward terminals 122b. In some examples, substrate inward terminals 122a can be exposed from proximate side of substrate 120 and substrate outward terminals 122b can be exposed from a distal side of substrate 120. In some examples, the thickness of conductive structure 122 can range from about 1 μm to about 50 μm. The thickness of conductive structure 122 can refer to individual layers of conductive structure 122. Conductive structure 122 can transmit signals, currents, or voltages within substrate 120.

Substrate 120 can comprise interleaved layers of dielectric structure 121 and conductive structure 122. Some embodiments can include a single layer of substrate passivation 123 between carrier 10 and dielectric structure 121. Although substrate 120 is depicted as having four layers of dielectric structure 121 alternating with four layers of conductive structure 122, the number of layers can be greater than or fewer than four. Substrate inward terminals 122a can comprise portions of conductive structure 122 (e.g., portions of inner conductive structure 122i) located in apertures 123a of substrate passivation 123 on the proximate or inner side of substrate 120. Substrate outward terminals 122b can comprise portions of conductive structure 122 exposed through dielectric structure 121 on the distal or outer side of substrate 120.

In accordance with various embodiments, substrate 120 can comprise an RDL substrate. RDL substrates can comprise one or more conductive redistribution layers and one or more dielectric layers and (a) can be formed layer by layer over an electronic device to where the RDL substrate is to be electrically coupled, or (b) can be formed layer by layer over a carrier that can be entirely removed or at least partially removed after the electronic device and the RDL substrate are coupled together. RDL substrates can be manufactured layer by layer as a wafer-level substrate on a round wafer in a wafer-level process, and/or as a panel-level substrate on a rectangular or square panel carrier in a panel-level process. RDL substrates can be formed in an additive buildup process and can include one or more dielectric layers alternatingly stacked with one or more conductive layers and define respective conductive redistribution patterns or traces configured to collectively (a) fan-out electrical traces outside the footprint of the electronic device, and/or (b) fan-in electrical traces within the footprint of the electronic device. The conductive patterns can be formed using a plating process such as, for example, an electroplating process or an electroless plating process. The conductive patterns can comprise an electrically conductive material such as, for example, copper or other plateable metal. The locations of the conductive patterns can be made using a photo-patterning process such as, for example, a photolithography process and a photoresist material to form a photolithographic mask. The dielectric layers of the RDL substrate can be patterned with a photo-patterning process, and can include a photolithographic mask through which light is exposed to photo-pattern desired features such as vias in the dielectric layers. The dielectric layers can be made from photo-definable organic dielectric materials such as, for example, polyimide (PI), BCB, or PBO. Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles, and could interfere with the light from the photo-patterning process. In some examples, such filler-free characteristics of filler-free dielectric materials can permit a reduction of the thickness of the resulting dielectric layer. Although the photo-definable dielectric materials described above can be organic materials, in some examples the dielectric materials of the RDL substrates can comprise one or more inorganic dielectric layers. Some examples of inorganic dielectric layer(s) can comprise silicon nitride (Si3N4), silicon oxide (SiO2), or silicon oxynitride (SiON). The inorganic dielectric layer(s) can be formed by growing the inorganic dielectric layers using an oxidation or nitridization process instead using photo-defined organic dielectric materials. Such inorganic dielectric layers can be filler-free, without strands, weaves, or other dissimilar inorganic particles. In some examples, the RDL substrates can omit a permanent core structure or carrier such as, for example, a dielectric material comprising bismaleimide triazine (BT) or FR4 and these types of RDL substrates can be referred to as a coreless substrate. Other substrates in this disclosure can also comprise an RDL substrate.

While substrate 120 is depicted in FIG. 2D as an RDL substrate, it is contemplated and understood that in some examples, substrate 120 can be a pre-formed substrate. The pre-formed substrate can be manufactured prior to attachment to an electronic device and can comprise dielectric layers between respective conductive layers. The conductive layers can comprise copper and can be formed using an electroplating process. The dielectric layers can be relatively thicker non-photo-definable layers and can be attached as a pre-formed film rather than as a liquid and can include a resin with fillers such as strands, weaves, and/or other inorganic particles for rigidity and/or structural support. Since the dielectric layers are non-photo-definable, features such as vias or openings can be formed by using a drill or laser. In some examples, the dielectric layers can comprise a prepreg material or ABF. The pre-formed substrate can include a permanent core structure or carrier such as, for example, a dielectric material comprising bismaleimide triazine (BT) or FR4, and dielectric and conductive layers can be formed on the permanent core structure. In other examples, the pre-formed substrate can be a coreless substrate and omits the permanent core structure, and the dielectric and conductive layers can be formed on a sacrificial carrier and is removed after formation of the dielectric and conductive layers and before attachment to the electronic device. The pre-formed substrate can rereferred to as a printed circuit board (PCB) or a laminate substrate. Such pre-formed substrate can be formed through a semi-additive or modified-semi-additive process. Other substrates in this disclosure can also comprise a pre-formed substrate.

FIG. 2E shows a cross-sectional view of electronic device 100 at a later stage of manufacture. FIG. 2EA is an enlarged view of electronic device 100 at region A in FIG. 2E. In FIG. 2E, carrier 20 is attached to the outer side of substrate 120, carrier 10 is removed from the inner side of substrate 120, and substrate 120 is flipped so substrate passivation 123 and the inner side of substrate 120 are positioned at an upper side of substrate 120. After flipping substrate 120, substrate outward terminals 122b can be positioned at the bottom side of substrate 120, and substrate inward terminal 122a can be positioned at the top side of substrate 120.

Carrier 20 can comprise temporary bond layer 21 provided on the surface of carrier 20. Temporary bond layer 21 of carrier 20 can be attached to substrate outward terminals 122b and dielectric structure 121 located at the bottom (or outer) side of substrate 120. Temporary bond layer 21 can be provided on the surface of carrier 20 by a coating method such as spin coating, doctor blade coating, casting, painting, spray coating, slot die coating, curtain coating, slide coating, or knife over edge coating, a printing method such as screen printing, pad printing, gravure printing, flexography printing, or offset printing, or an inkjet printing method, an intermediate technology between coating and printing, or can be provided by direct attachment of a bonding film or bonding tape. In some examples, temporary bond layer 21 can be referred to as a temporary bonding film, a temporary bonding tape, or a temporary adhesive coating. For example, the temporary bonding layer can be a heat release tape (film) or an optical release tape (film), in which the adhesive strength is weakened or removed by heat or light, respectively. Temporary bond layer 21 can allow carrier 20 to be separated from substrate 120 before substrate interconnects 130 are provided, as will later be described.

In the example shown in FIGS. 2E and 2EA, a portion of seed 122s covering substrate inward terminal 122a can be removed. In some examples, seed 122s covering substrate inward terminal 122a can be removed through etching to expose a top side of substrate inward terminal 122a. The top side of substrate passivation 123 can protrude upward more than the top side of substrate inward terminal 122a by a height approximately equal to the height of seed layer 122s over substrate inward terminal 122a before removal. Substrate inward terminal 122a can be dished or recessed relative to substrate passivation 123 by a height approximately equal to the thickness of seed layer 122s. In some examples, the thickness of seed layer 122s and/or the dishing depth or dishing distance D of the top side of substrate inward terminal 122a can be between approximately 0.01 μm to 0.1 μm, 0.01 μm to 0.05 μm, or 0.01 μm to 0.03 μm. Stated differently, a distance D between the top side of substrate passivation 123 and the top side of substrate inward terminal 122a can be approximately 0.01 μm to 0.1 μm, 0.01 μm to 0.05 μm, or 0.01 μm to 0.03 μm.

FIG. 2F shows a cross-sectional view of electronic device 100 at a later stage of manufacture. FIG. 2FA is an enlarged view of electronic device 100 at region A of FIG. 2F before hybrid bonding, and FIG. 2FB shows electronic device 100 at region A of FIG. 2F after hybrid bonding. In the example shown in FIGS. 2F, 2FA and 2FB, electronic component 110 can be provided on the top side of substrate 120.

In some examples, pick-and-place equipment can pick up electronic component 110 and place it to allow component interconnects 111 of electronic component 110 to be positioned at the top side of substrate inward terminals 122a of substrate 120. Component passivation layer 113 of electronic component 110 can be in contact with substrate passivation 123 of substrate 120. Component interconnects 111 of electronic component 110 can be spaced apart from substrate inward terminal 122a of substrate 120 by void 124. Void 124 can have a height approximately equal to the dishing height or recessed height of the top surface of inner terminal 122a beneath the top surface of substrate passivation 123.

In some examples, the passivation bond between component passivation layer 113 and substrate passivation layer 123 can initially start as a Van der Waals bond that progresses to a covalent bond through time or temperature. With the passivation bond secured, component interconnect 111 and substrate inward terminal 122a can be urged towards each other until void 124 is closed by applying a bonding temperature. A direct bond can be established between component interconnect 111 and substrate inward terminal 122a. Bonding can be achieved between passivation layer 113 and substrate passivation 123 through a heat treatment process. For example, bonding between passivation layer 113 and substrate passivation 123 can be achieved at low temperatures through surface activation prior to bonding. For example, by performing surface activation on passivation layer 113 and substrate passivation 123, hydrogen (H) can be generated on the surfaces of passivation layer 113 and substrate passivation 123 through plasma treatment, oxygen (O) particles separated from water or air during plasma treatment can bind to hydrogen (H) on the surfaces of passivation layer 113 and substrate passivation 123, and hydroxyl (OH) groups can be induced on the surfaces of passivation layer 113 and substrate passivation 123, respectively. Bonding between passivation layer 113 and substrate passivation 123 can be easily bonded at low temperatures. In some examples, passivation layer 113 and substrate passivation 123 can be bonded to each other at temperatures ranging from approximately 25° C. to approximately 400° C. As used herein to describe temperatures, the term approximately can mean +/−5%, +/−10%, +/−15%, +/−20%, or +/−25%.

After passivation layer 113 of electronic component 110 and substrate passivation 123 of substrate 120 are initially bonded, component interconnect 111 of electronic component 110 and substrate inward terminal 122a of substrate 120 can be spaced apart from each other by void 124, as shown in FIG. 2FA.

Component interconnect 111 and substrate inward terminal 122a can be bonded at a higher temperature than the temperature at which passivation layer 113 and substrate passivation 123 are bonded. For example, component interconnects 111 of electronic component 110 and substrate inward terminal 122a of substrate 120 can be bonded by a thermal compression process. In some examples, component interconnect 111 and substrate inward terminal 122a can be bonded in response to bonding temperatures ranging from approximately 150° C. to approximately 400° C. In some examples, the direct bond between component interconnect 111 and substrate inward terminal 122a can comprise or be referred as a fusion bond or a solderless bond. In some examples, the direct bond can comprise grain growth of the material of component interconnect 111 and substrate inward terminal 122a into each other. In some examples, a direct bond can be established by pressure from component interconnect 111 and substrate inward terminal 122a expanding towards each other due to heat while secured by the bond between passivation layer 113 and substrate passivation layer 123.

Due to an increase in temperature, component interconnect 111 and substrate inward terminal 122a can expand filling void 124 to contact and bond with each other. Component interconnect 111 and substrate inward terminal 122a can have a larger thermal expansion coefficient than passivation layer 113 and substrate passivation 123. A separation distance (e.g., the height of void 124) between component interconnect 111 and substrate inward terminal 122a can compensate for the expansion due to temperature when bonding component interconnect 111 and substrate inward terminal 122a. Component interconnects 111 and substrate inward terminal 122a can be bonded together by the thermal compression process as their respective surfaces contact one another and metals diffuse from component interconnects 111 and/or substrate inward terminal 122a across bond boundary 125.

Substrate 120 can define void 124 in the space left behind after removing seed 122s. A terminal end of seed 122s can be spaced from bond boundary 125 by a thickness of the removed portion of seed 122s. Removing seed 122s can control dishing depth by stripping away material equal the thickness or height of seed 122s above substrate inward terminals 122a. Etching away seed 122s can create dishing depth without applying a separate CMP process or other dishing adjustment to achieve a suitable height of void 124. By avoiding additional dishing adjustments, the exposed side of substrate inward terminal 122a can be substantially smooth. As used herein, the term substantially smooth can describe a surface devoid of burrs, grooving, or other imperfections typically left behind after CMP processes. Using the thickness of seed 122s to regulate dishing depth can also allow for greater control and/or a more precise dishing depth.

In some examples, controlling the height of void 124 (e.g., controlling the thickness of the seed 122s that is removed to form void 124) can compensate for the difference in thermal expansion between passivation layers 113 and 123, component interconnects 111, and conductive structure 122. Electronic component 110 and substrate 120 can enable low-temperature hybrid bonding by bonding passivation layer 113 and substrate passivation 123, which allows component interconnects 111 and substrate inward terminals 122a to expand into contact with one another and bond with one another at suitable temperatures (e.g., approximately 150° C. to approximately 400° C.).

FIG. 2G shows a cross-sectional view of electronic device 100 at a later stage of manufacture. In the example shown in FIG. 2G, encapsulant 140 can be provided over the top (or inner) side of substrate 120 and around the lateral sides of electronic components 110. Encapsulant 140 can be in contact with the top side of substrate 120 and the top side and sidewalls of electronic components 110. Thereafter, the upper portion of encapsulant 140 can be removed to expose a top side of electronic component 110. Encapsulant 140 can be coupled to substrate passivation 123 outside a footprint of bond boundary 125.

In some examples, encapsulant 140 can comprise or be referred to as a body or a molding. For example, encapsulant 140 can comprise an epoxy mold compound, resin, filler-reinforced polymer, a B-stage pressed film, or gel. For example, encapsulant 140 can be provided by compression molding, transfer molding, liquid body molding, vacuum lamination, paste printing, or film assisted molding.

In some examples, the upper portion of encapsulant 140 can be removed by grinding. In some examples, a top side of encapsulant 140 can be coplanar with the top side of electronic component 110. In some examples, the thickness of encapsulant 140 can range from approximately 10 μm to approximately 500 μm.

FIG. 2H shows a cross-sectional view of electronic device 100 at a later stage of manufacture. In the example shown in FIG. 2H, substrate interconnects 130 can be provided on substrate outward terminals 122b of substrate 120.

Before substrate interconnects 130 are provided, carrier 20 (FIG. 2G) can be separated from the bottom side of substrate 120. In some examples, after the adhesive force of temporary bond layer 21 interposed between carrier 20 and substrate 120 is removed or reduced by applying heat, light, chemical solution, or physical external force, carrier 20 can be separated from the bottom side of substrate 120. As carrier 20 is removed, substrate outward terminals 122b can be exposed at the bottom (or outer) side of substrate 120.

In some examples, before carrier 20 is removed, carrier 30 can be attached to the top side of encapsulant 140 and the top side of electronic components 110. Carrier 30 can comprise similar elements, features, materials, or formation processes to those of carrier 20.

Substrate interconnects 130 can be in contract with and coupled to substrate outward terminals 122b of substrate 120. In some examples, substrate interconnects 130 can comprise tin (NS), silver (Ag), lead (Pb), copper (Cu), Sn—Pb, Sn37-Pb, Sn95-Pb, Sn—Pb—Ag, Sn—Cu, Sn—Ag, Sn—Au, Sn—Bi, or Sn—Ag—Cu. For example, after a conductive material containing solder is formed on substrate outward terminal 122b using a ball drop method, substrate interconnects 130 can be provided through a reflow process. Substrate interconnects 130 can comprise or be referred to as conductive balls such as solder balls, conductive pillars (e.g., kappa pillars), or conductive posts having solder caps. In some examples, substrate interconnects 130 can be a ball grid array or land grid array outside substrate 120. In some examples, the size of substrate interconnects 130 can range from approximately 10 μm to approximately 500 μm. Substrate interconnects 130 can be electrically connected to electronic component 110 through substrate 120.

In some examples, multiple electronic devices 100 can be manufactured at the same time, for example, on a panel or carrier. The electronic devices 100 can be separated into individual electronic devices 100 by a singulation process. For example, individual electronic devices 100 can be provided by singulating (e.g., cutting, sawing, dicing, etc.) through encapsulant 140 and substrate 120. In some examples, the lateral sides of encapsulant 140 and substrate 120 can be coplanar in response to singulation.

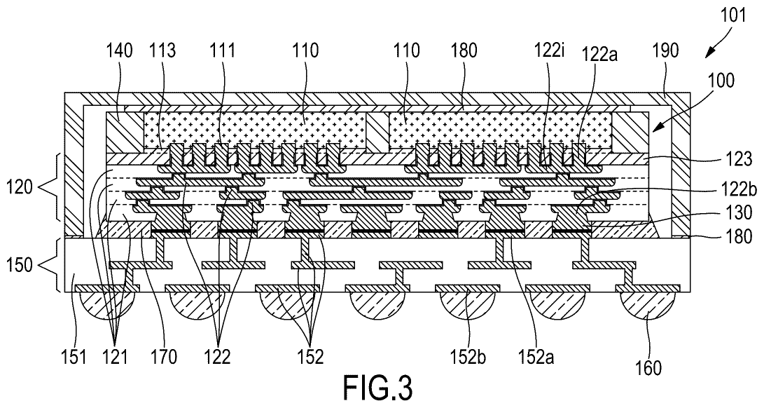

FIG. 3 shows an example electronic device 101. In accordance with various examples, electronic device 101 can comprise electronic device 100, base substrate 150, external interconnects 160, adhesive layer 180, and lid 190. In some examples, electronic device 101 can comprise underfill 170.

Base substrate 150 can comprise base-substrate dielectric structure 151 and base-substrate conductive structure 152. Base-substrate conductive structure 152 can comprise base-substrate inward terminals 152a and base-substrate outward terminals 152b. Substrate interconnects 130 can couple electronic device 100 to conductive structure 152 of base substrate 150. For example, substrate interconnects 130 can be coupled between outward terminals 122b of substrate 120 and base-substrate inward terminals 152a.

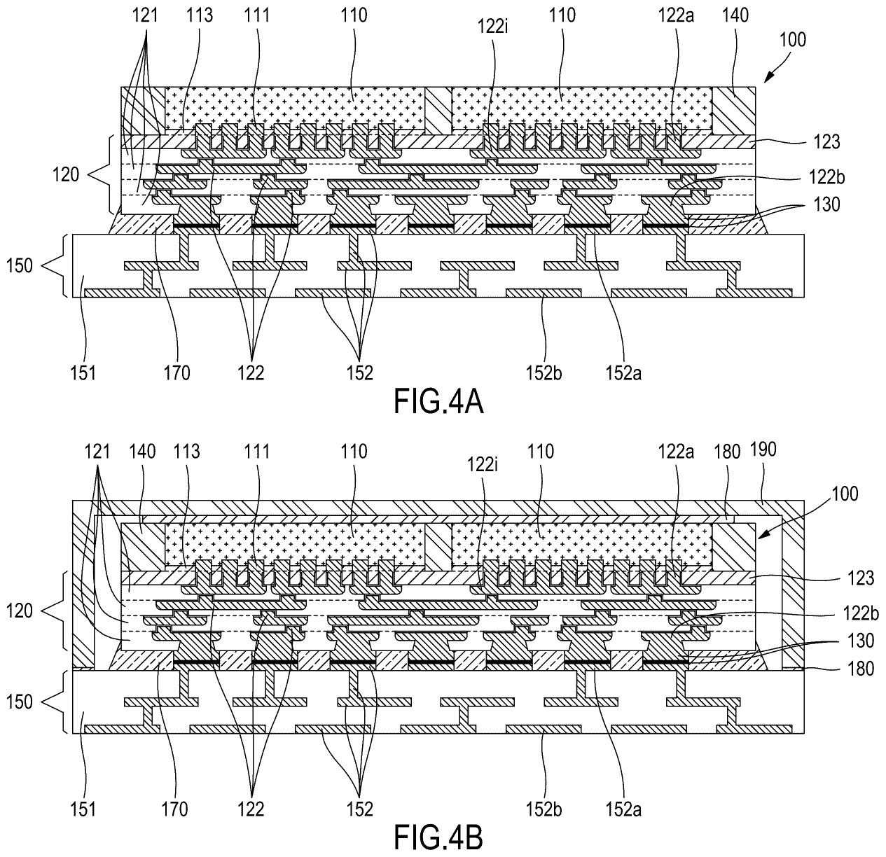

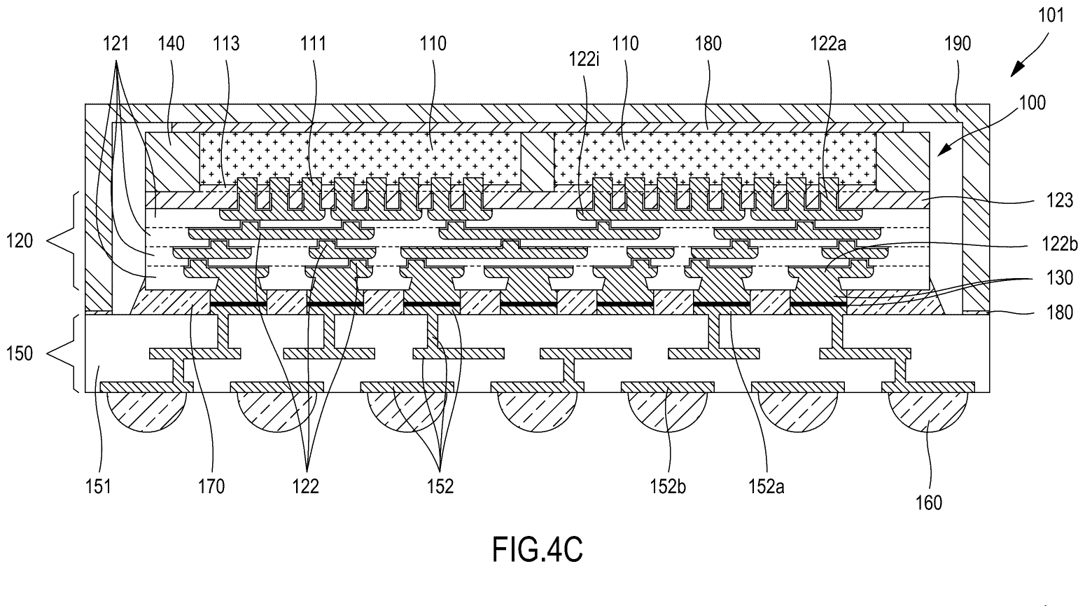

FIG. 4A shows a cross-sectional view of electronic device 101 during manufacture. In the example shown in FIG. 4A, electronic device 100 can be disposed over substrate 150 using, for example, pick and place equipment. Substrate interconnects 130 can be seated on base-substrate inward terminals 152a.

Base substrate 150 can comprise base-substrate dielectric structure 151 and base-substrate conductive structure 152. In some examples, base-substrate dielectric structure 151 can comprise or be referred to as one or more dielectric layers. For instance, the one or more dielectric layers can comprise a core layer, polymer layers, pre-preg layers, or solder mask layers stacked on each other. One or more layers or elements of base-substrate conductive structure 152 can be interposed or embedded between the one or more layers of base-substrate dielectric structure 151. The upper and lower sides of base-substrate dielectric structure 151 can comprise part of the inner side and outer side of base substrate 150, respectively. In some examples, base-substrate dielectric structure 151 can comprise a polymer, PI, BCB, PBO, BT, ABF, or resin. In some examples, the thickness of base-substrate dielectric structure 151 can range from approximately 10 μm to 500 μm.

Base-substrate conductive structure 152 can comprise one or more conductive layers that define conductive paths with elements such as traces, pads, vias, and wiring patterns, for example. Base-substrate conductive structure 152 can comprise base-substrate inward terminals 152a on the inner side of base substrate 150 and base-substrate outward terminals 152b on the outer side of base substrate 150.

Base-substrate inward terminals 152a and base-substrate outward terminals 152b can be provided on the inner side and the outer side, respectively, of base substrate 150 in a matrix or array having rows or columns. In some examples, base-substrate inward terminals 152a or base-substrate outward terminal 152b can comprise or be referred to as a conductor, a conductive material, a substrate land, a conductive land, a substrate pad, a wiring pad, a connection pad, a micro pad, or UBM. The thicknesses of base-substrate inward terminal 152a or base-substrate outward terminal 152b can range from approximately 1 μm to 50 μm. Base-substrate inward terminals 152a can be in contact with and coupled to substrate interconnects 130. Substrate interconnects 130 can be bonded to base-substrate inward terminals 152a using a reflow or thermal compression process. Base-substrate conductive structure 152 of base substrate 150 can be electrically connected to component interconnects 111 of electronic component 110 through substrate interconnects 130 and conductive structure 122 of substrate 120.

In some examples, base substrate 150 can comprise or be referred to as a rigid substrate, a flexible laminate substrate, a ceramic substrate, a glass substrate, a silicon substrate, a printed circuit board, a multilayer substrate, a laminate substrate, or a molded lead frame. In some examples, base substrate 150 can comprise or be referred to as an RDL substrate, a buildup substrate, or a coreless substrate. In some example, base substrate 150 can have an area varying according to the area of electronic device 100. In some example, base substrate 150 can have an area of about 3 mm×3 mm to about 150 mm×150 mm. In some example, base substrate 150 can have a thickness ranging from about 0.1 mm to about 7 mm. In some examples, base substrate 150 can comprise similar elements, features, materials, or formation processes to those of substrate 120.

In some examples, underfill 170 can be positioned between substrate 120 and base substrate 150. Underfill 170 can be in contact with the bottom side of substrate 120 and the inner or upper side of base substrate 150. Underfill 170 can be in contact with substrate interconnects 130. Underfill 170 can comprise or be referred to as a dielectric layer or a nonconductive paste. Underfill 170 can be devoid of inorganic fillers. In some examples, underfill 170 can comprise or be referred to as CUF, NCP, NCF, ACF, or ACP. In some examples, after being inserted between substrate 120 and base substrate 150, underfill 170 can be hardened. In some examples, after underfill 170 is provided to cover the inside of base substrate 150, substrate interconnects 130 coupled to substrate outward terminal 122b of substrate 120 can penetrate underfill 170 and be connected to base-substrate inward terminal 152a of base substrate 150. Underfill 170 can prevent substrate interconnects 130 between substrate 120 and base substrate 150 from separating due to physical and chemical shock.

FIG. 4B shows a cross-sectional view of electronic device 101 at a later stage of manufacture. In the example shown in FIG. 4B, lid 190 can be provided over base substrate 150. Lid 190 can be coupled to the inner side of base substrate 150 to surround electronic device 100 (e.g., surrounding electronic component 110 and substrate 120). Lid 190 can comprise a substantially square top plate and side walls extending downward from an edge of the top plate. The lower surface of the side wall of lid 190 can be attached and fixed to the inside of base substrate 150 through adhesive layer 180. The lower side of lid 190 and the upper side of electronic component 110 can be attached and fixed through adhesive layer 180. For example, adhesion layer 180 can comprise or be referred to as an adhesive, thermal interface material (TIM), or solder. In some examples, adhesive layer 180 between the upper side of lid 190 and the upper side of electronic component 110 can comprise or be referred to as a thermal interface material (TIM). Adhesive layer 180 can comprise a thermally conductive material and can be in contact with the top side of electronic component 110 and the bottom side of the upper plate of lid 190. In some examples, adhesive layer 180 can comprise a polymer type thermal interface material, such as silicone, epoxy, or urethane with highly thermal conductive fillers, such as graphite, boron nitride, silver, aluminum, or aluminum oxide. Since thermal interface material includes a thermally conductive material, heat generated from electronic component 110 can be easily transferred to lid 190.

Lid 190 can be made of a metal having high heat conduction and radiation. In some examples, lid 190 can comprise aluminum or copper. In some examples, lid 190 can be referred to as or comprise a heat sink, a heat dissipation plate, a cap cover, a lid, a shield, or a body. In some examples, trenches, protrusions, or fins can be provided on the upper side of lid 190 to improve heat dissipation efficiency. The thickness of lid 190 can range from approximately 300 μm to approximately 2000 μm.

FIG. 4C shows a cross-sectional view of electronic device 101 at a later stage of manufacture. In the example shown in FIG. 4C, external interconnects 160 can be provided on base-substrate outward terminals 152b of base substrate 150. External interconnects 160 can comprise elements, features, materials, or formation processes similar to or the same as those of substrate interconnects 130.

External interconnects 160 can be electrically connected to electronic component 110 through base-substrate conductive structure 152 of base substrate 150, substrate interconnects 130, conductive structure 122 of substrate 120, and component interconnects 111. In some examples, the size of external interconnects 160 can range from approximately 1 μm to approximately 1000 μm. In some examples, external interconnects 160 can be referred to as external input/output terminals of electronic device 100.

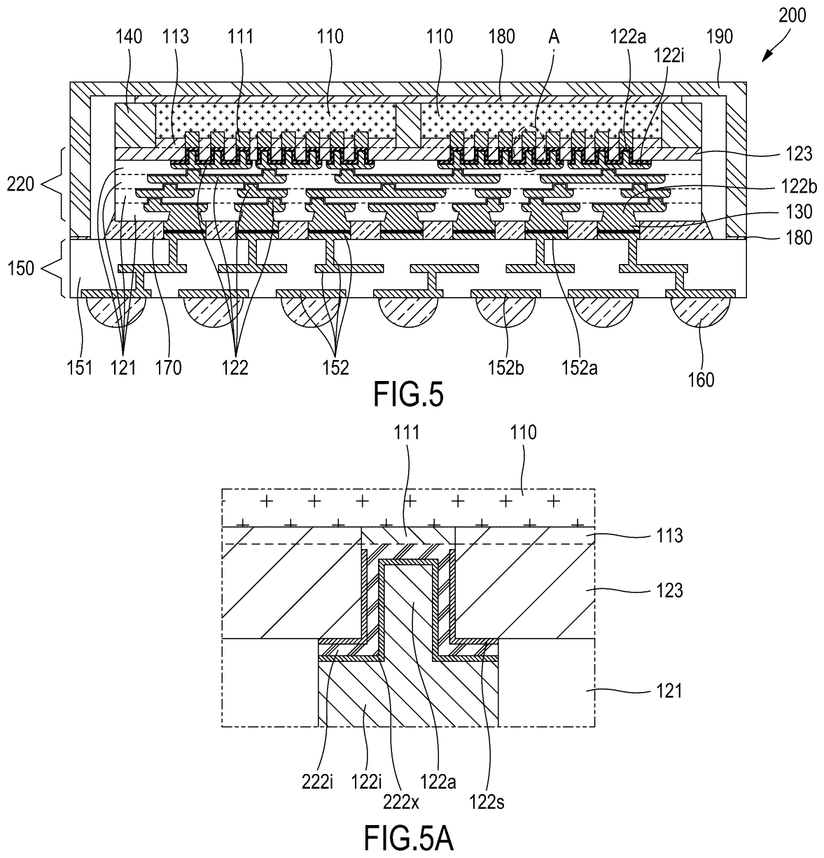

FIG. 5 shows a cross-sectional view of an example electronic device 200. FIG. 5A is a detailed view of electronic device 200 in region A of FIG. 5. In the example shown in FIGS. 5 and 5A, electronic device 200 can comprise electronic component 110, substrate 220, substrate interconnects 130, encapsulant 140, base substrate 150, external interconnects 160, adhesive layer 180, and lid 190. In some examples, electronic device 200 can comprise underfill 170.

Electronic device 200 can be similar to electronic device 101 in FIG. 3. For example, electronic device 200 can be similar to electronic device 101 in terms of electronic component 110, substrate interconnects 130, encapsulant 140, base substrate 150, external interconnects 160, underfill 170, adhesive layer 180, and lid 190.

In accordance with various examples, substrate 220 can comprise dielectric structure 121, conductive structure 122, and substrate passivation 123. Conductive structure 122 can comprise substrate inward terminals 122a, seed 122s, inner conductive structure 122i, interface layer 222i, barrier layer 222x, and substrate outward terminals 122b.

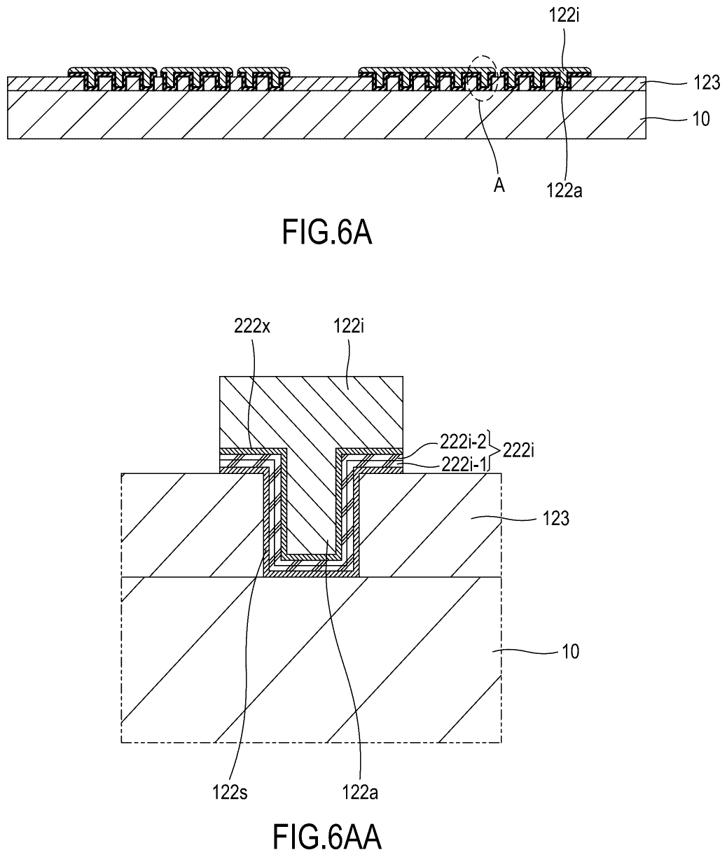

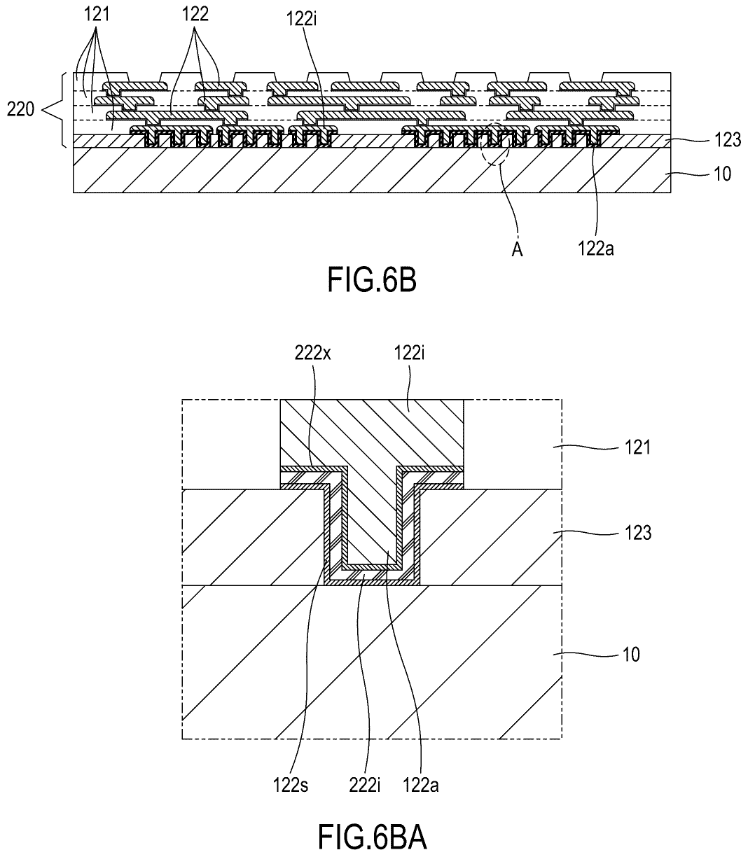

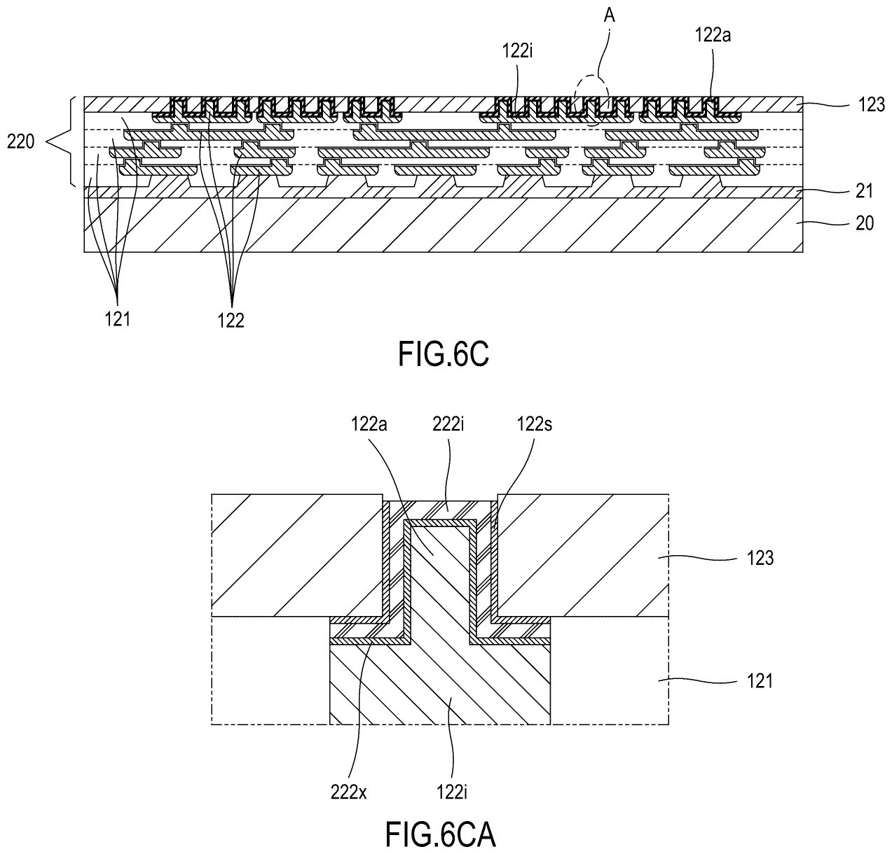

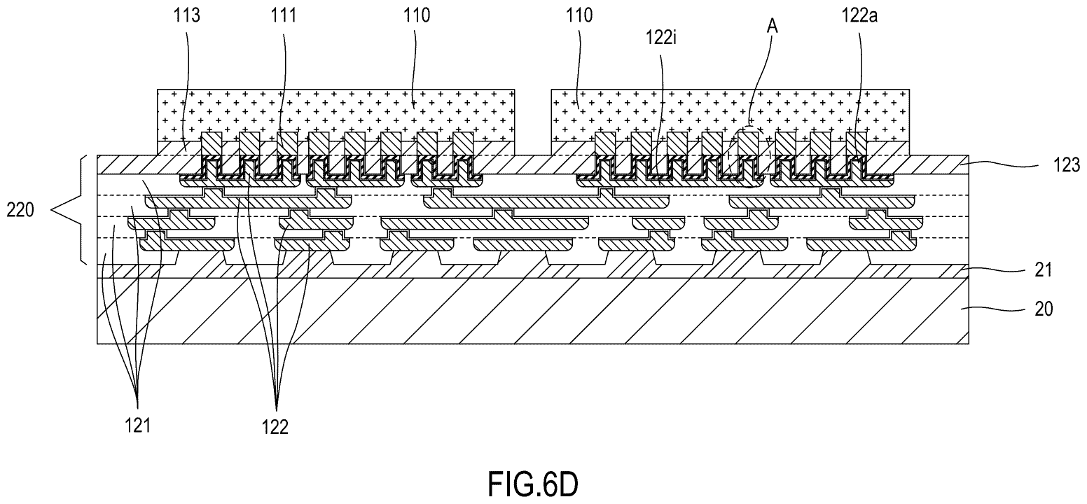

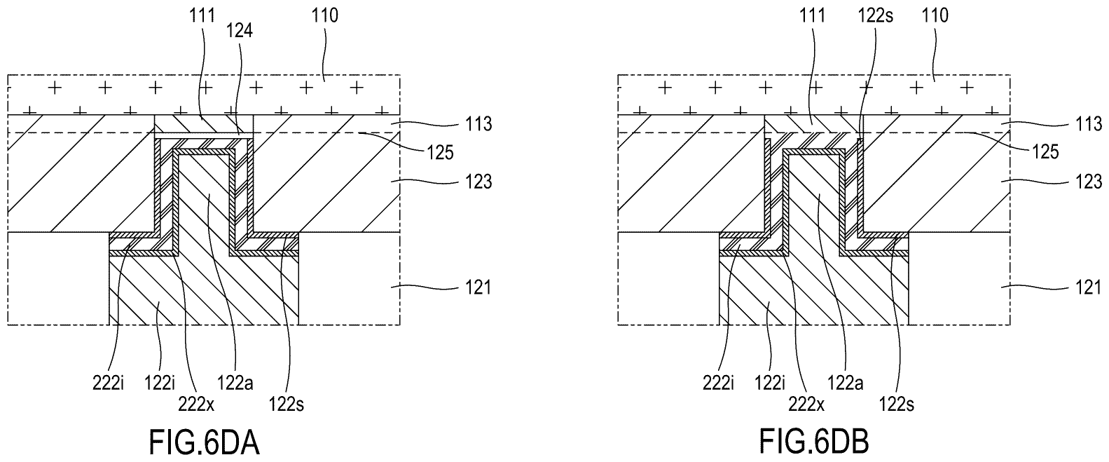

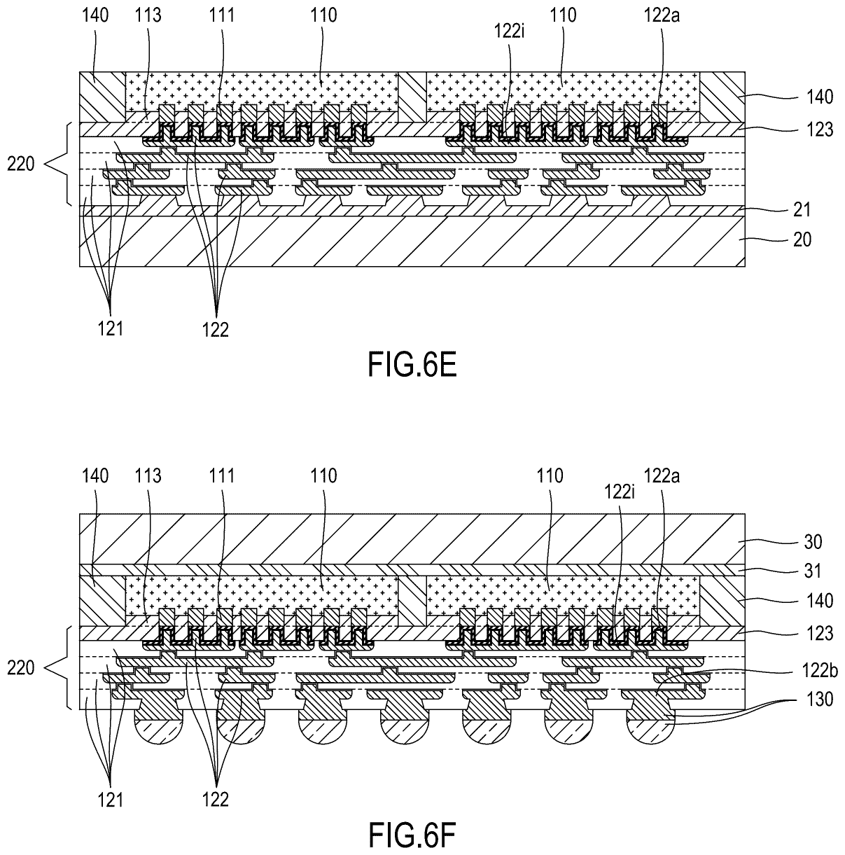

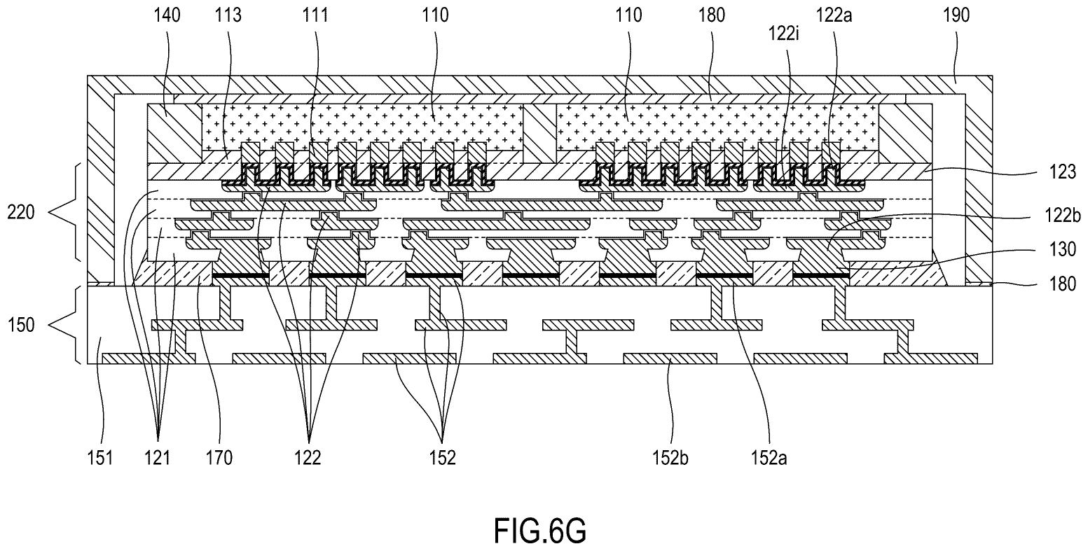

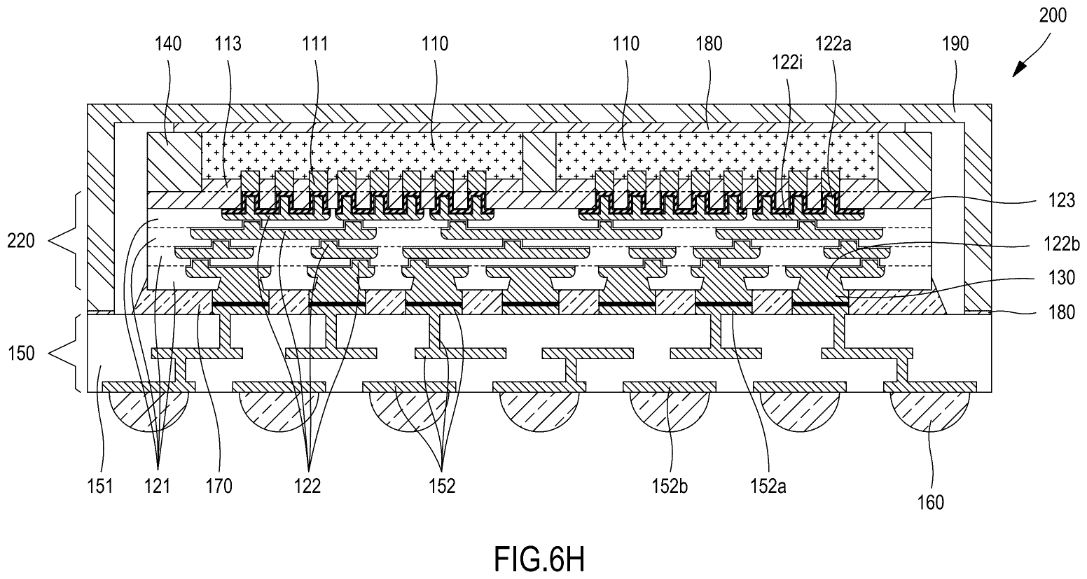

FIGS. 6A to 6H show cross-sectional views of an example method for manufacturing an example electronic device 200. Electronic device 200 shown in FIG. 6A is shown in a cross-sectional view after the method for manufacturing electronic device 100 shown in FIGS. 2A and 2B.

FIG. 6A shows a cross-sectional view of electronic device 200 at a later stage of manufacture. FIG. 6AA is a detailed view of region A in FIG. 6A. In the example shown in FIGS. 6A and 6AA, interface layer 222i, barrier layer 222x, and inner conductive structure 122i can be provided to over seed 122s.

In accordance with various embodiments, interface layer 222i can be provided over seed 122s on the upper side of seed 122s. Interface layer 222i can be provided by electroless plating, electrolytic plating, sputtering, PVD, CVD, MOCVD, ALD, LPCVD, or PECVD. In various examples, interface layer 222i can comprise Au or Ag. In some examples, interface layer 222i can be a multi-layer metal layer, at least initially, where Cu and Au or Cu and Ag are sequentially stacked. For example, interface layer 222i can include a first interface portion 222i-1 comprising a first metal (e.g., Cu) located on seed 122s and a second interface portion 222i-2 comprising a second metal (e.g., Au or Ag) located on first interface portion 222i-1. In some examples, the thickness of interface layer 222i can range from approximately 0.05 μm to approximately 10 μm.

In accordance with various examples, barrier layer 222x can be provided over interface layer 222i on the upper side of interface layer 222i. Barrier layer 222x can be provided by electroless plating, electrolytic plating, sputtering, PVD, CVD, MOCVD, ALD, LPCVD, or PECVD. Barrier layer 222x can comprise or be referred to as an isolation layer. In some examples, barrier layer 222x can comprise Ni, Co, Fe, Ti, TiW, W, Cr, or Al. In some examples, the thickness of barrier layer 222x can range from approximately 0.05 μm to approximately 10 μm.

Interface layer 222i and barrier layer 222x can be provided to have multiple patterns, and the respective patterns can be coupled to seed 122s. In some examples, first interface portion 222i-1 can be formed using, for example, PVD and can completely cover seed 122s and substrate passivation 123 (similar to seed 122s in FIG. 2B). After providing seed 122s and first interface portion 222i-1, a patterned mask (e.g., a photo resist) can be provided over first interface portion 222i-1 and seed 122s. The patterned mask can include openings exposing areas of first interface portion 222i-1. Second interface portion 222i-2, barrier layer 222x, and inner conductive structure 122i can be formed (e.g., plated) in the patterned mask openings over first interface portion 222i-1. After forming second interface portion 222i-2, barrier layer 222x, and inner conductive structure 122i, the patterned mask can be removed. Removal of the patterned mask exposes sections of first interface portion 222i-1 that are not located under (e.g., are not vertically aligned with) second interface portion 222i-2, barrier layer 222x, and inner conductive structure 122i. These exposed sections of first interface portion 222i-1 and the seed 122s located thereunder can then be removed using, for example, etching, thereby exposing portions of substrate passivation 123. After removal of the sections of the first interface portion 222i-1 and seed 122s that are not covered by second interface portion 222i-2, barrier layer 222x, and inner conductive structure 122i, seed 122s, interface layer 222i, barrier layer 222x, and inner conductive structure 122i can have the same pattern.

Inner conductive structure 122i can comprise similar elements, features, materials, or formation processes to those of inner conductive structure 122i of electronic device 100. Substate inward terminal 122a can comprise the portion of inner conductive structure 122i located in aperture 123a (FIG. 2A).

FIG. 6B shows a cross-sectional view of electronic device 200 at a later stage of manufacture. FIG. 6BA is a detailed view of region A in FIG. 6B. In the example shown in FIGS. 6B and 6BA, substrate 220 can be provided by sequentially alternating or interleaving dielectric structure 121 and conductive structure 122 to cover inner conductive structure 122i. Substrate 220 can comprise elements, features, materials, or formation processes similar to or the same as those of substrate 120 of electronic device 100.

After dielectric structure 121 is provided and in response to application of an alloying temperature, interface layer 222i can be transformed from a stacked (or distinct) metal layer structure into an alloy. For example, prior to application of the alloying temperature, interface layer 222i can comprise distinct regions of different metals (e.g., first interface portion 222i-1 (FIG. 6AA) comprising Cu and second interface portion 222i-2 comprising Au), which in response to application of the alloying temperature can form an alloy (e.g., a AuCu alloy) when heated due to the diffusion characteristics of Au. The AuCu alloy can be formed by applying alloying temperatures ranging from approximately 200° C. to approximately 400° C., which are below the melting points of the individual metals (approximately 1,064° C. for Au and approximately 1,085° C. for Cu). Barrier layer 222x can prevent gold (Au) in interface layer 222i from diffusing toward inner conductive structure 122i. Interface layer 222i can be interposed between seed 122s and barrier layer 222x. Barrier layer 222x can be interposed between interface layer 222i and inner conductive structure 122i. In accordance with various examples, substrate inward terminals 122a can include portions of interface layer 222i, barrier layer 222x, seed 122s, and inner conductive structure 122i bounded by lateral sidewalls of substrate passivation 123 (i.e., portions of interface layer 222i, barrier layer 222x, seed 122s, and inner conductive structure 122i located in apertures 123a of FIG. 2A). In some examples, the alloying temperature can be applied during the curing of one or more of the dielectric layers of dielectric structure 121. For example, the curing temperature of dielectric structure 121 can be equal to or greater than the alloying temperature, such that interface layer 222i turns from stacked metal layers into an alloy during the curing process.

FIG. 6C shows a cross-sectional view of electronic device 200 at a later stage of manufacture. FIG. 6CA is a detailed view of region A in FIG. 6C. In the example shown in FIGS. 6C and 6CA, seed 122s covering interface layer 222i can be removed to expose interface layer 222i. In some examples, seed 122s covering interface layer 222i can be removed by etching, thereby exposing a top side of interface layer 222i. The top side of substrate passivation 123 can protrude above the top side of interface layer 222i. The top side of interface layer 222i can be recessed or dished relative to the top side of substrate passivation 123. The distance that the top side of interface layer 222i is recessed relative to the top side of substrate passivation 123 can be the referred to as the dishing height or dishing depth and can be approximately 0.01 μm to 0.1 μm, 0.01 μm to 0.05 μm, or 0.01 μm to 0.03 μm, for example. Techniques used to remove seed 122s from substrate 220 can be similar to the or the same as techniques used to remove seed 122s from substrate 120 of electronic device 100.

FIG. 6D shows a cross-sectional view of electronic device 200 at a later stage of manufacture. FIG. 6DA is a detailed view of region A of FIG. 6D during hybrid bonding, and FIG. 6 DB shows region A of FIG. 6DA after hybrid bonding. In the example shown in FIGS. 6D, 6DA, and 6 DB, electronic component 110 can be provided at a top side of substrate 220. Electronic component 110 of electronic device 200 can comprise elements, features, materials, or formation techniques similar to those of electronic component 110 of electronic device 100. For example, techniques similar to those depicted and described with reference to FIGS. 2F, 2FA, and 2FB can be used on electronic device 200 of FIGS. 6D, 6DA, and 6 DB.

In some examples, pick-and-place equipment can pick up electronic component 110 and place it with component interconnects 111 of electronic component 110 positioned over the top side of interface layer 222i of substrate inward terminal 122a. Passivation layer 113 of electronic component 110 can be in contact with substrate passivation 123 of substrate 220. Component interconnects 111 can be spaced apart from interface layer 222i of substrate inward terminal 122a by void 124. Passivation layer 113 and substrate passivation 123 can be bonded to each other by heat treatment. After passivation layer 113 of electronic component 110 and substrate passivation 123 of substrate 220 are bonded to each other, component interconnects 111 of electronic component 110 and interface layer 222i of substrate 220 can be spaced apart from each other by void 124, as shown in FIG. 6DA.

FIG. 6 DB depicts component interconnects 111 of electronic component 110 and interface layer 222i of substrate 120 bonded to each other. A thermal compression process can be applied causing interface layer 222i to extend across void 124 and contact component interconnects 111. Component interconnects 111 and interface layer 222i can be bonded together by the thermal compression process as the metals diffuse into each other across bond boundary 125. Interface layer 222i can be bonded more readily or quickly to component interconnects 111 of electronic component 110 due to diffusion characteristics of the alloy of interface layer 222i. For example, diffusion characteristics Au can cause an interface layer 222i that comprises an AuCu alloy to bond more readily and/or quickly as compared to Cu alone).

FIG. 6E shows a cross-sectional view of electronic device 200 at a later stage of manufacture. In the example shown in FIG. 6E, encapsulant 140 can be provided over the top side of substrate 220 and electronic components 110. Encapsulant 140 can comprise similar elements, features, materials, or formation processes to those of encapsulant 140 of electronic device 100.

FIG. 6F shows a cross-sectional view of electronic device 200 at a later stage of manufacture. In the example shown in FIG. 6F, substrate interconnects 130 can be provided to substrate outward terminals 122b of substrate 220. Substrate interconnects 130 can comprise similar elements, features, materials, or formation processes to those of substrate interconnects 130 of electronic device 100. In some examples, multiple electronic devices 200 (e.g., multiple substrates 220 with electronic components 110 coupled thereto and encapsulant 140 deposited thereover) can be manufactured at the same time, for example, on a panel or carrier. The electronic devices can be separated into individual electronic devices 200 (e.g., individual substrates 220 with one or more electronic component(s) 110 coupled thereto and encapsulant 140 deposited thereover) by a singulation process. For example, the individual electronic devices can be provided by singulating (e.g., cutting, sawing, dicing, etc.) through encapsulant 140 and substrate 220. In some examples, the lateral sides of encapsulant 140 and substrate 220 can be coplanar in response to singulation.

FIG. 6G shows a cross-sectional view of electronic device 200 at a later stage of manufacture. In the example shown in FIG. 6G, substrate interconnects 130 can be seated on base substrate 150. In some examples, underfill 170 can be positioned between substrate 220 and base substrate 150. Base substrate 150 and underfill 170 can comprise elements, features, materials, or formation processes similar to those of base substrate 150 and underfill 170 of electronic device 101.

FIG. 6H shows a cross-sectional view of electronic device 200 at a later stage of manufacture. In the example shown in FIG. 6H, lid 190 can be provided on the inside of base substrate 150, and external interconnects 160 can be provided on base-substrate outward terminal 152b of base substrate 150. Lid 190 can be attached and fixed to base substrate 150 and electronic component 110 through adhesive layer 180. Lid 190, external interconnects 160, and adhesive layer 180 can comprise elements, features, materials, or formation processes similar to those of lid 190, external interconnects 160, and adhesive layer 180 of electronic device 101.

The devices and methods described herein tend to improve pitch and bonding performance in electronic devices. Dishing depths can be tightly controlled by removing a seed layer over a conductive structure to leave a void. The dishing depth is typically equal to the height of the removed seed layer, and the dishing depth can be selected to compensate for coefficients of thermal expansion of the dished conductive structures and of the adjacent passivation layers. Some examples can include alloyed conductive structures to further bonding speeds due to diffusion characteristics of the alloyed metals.

The present disclosure includes reference to certain examples; however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

1. An electronic device, comprising:
an electronic component;
a component passivation layer coupled to the electronic component;
a component interconnect extending from the electronic component through the component passivation layer;
a substrate coupled to the component passivation layer and the component interconnect, the substrate comprising:
a substrate passivation layer coupled to the component passivation layer along a bond boundary, wherein the substrate passivation layer comprises an inorganic material;
a substrate inward terminal extending through the substrate passivation layer and coupled to the component interconnect along the bond boundary;
a seed between the substrate passivation layer and the substrate inward terminal;
a dielectric structure coupled to the substrate passivation layer; and
a conductive structure extending through the dielectric structure and coupled to the substrate inward terminal.

2. The electronic device of claim 1, wherein the substrate inward terminal comprises a gold-copper alloy.

3. The electronic device of claim 1, wherein the substrate passivation layer is bonded to the component passivation layer by covalent bonding along the bond boundary.

4. The electronic device of claim 3, wherein the component interconnect is bonded to the substrate inward terminal in response to a metal from the substrate inward terminal migrating across the bond boundary.

5. The electronic device of claim 4, wherein the metal from the substrate inward terminal comprises gold.

6. The electronic device of claim 1, wherein a terminal end of the seed is spaced from the bond boundary by a thickness of the seed.

7. The electronic device of claim 1, wherein the dielectric structure comprises an organic material.

8. The electronic device of claim 1, further comprising a base substrate coupled to the substrate, the base substrate including:
a base-substrate dielectric structure coupled to the dielectric structure of the substrate; and
a base-substrate conductive structure interleaved with the base-substrate dielectric structure and coupled to the conductive structure of the substrate.

9. A method of manufacturing an electronic device, comprising:
providing a substrate passivation layer defining an aperture and comprising an inorganic material;
providing a seed over the substrate passivation layer and in the aperture;
providing a conductive structure over the seed and in the aperture, the conductive structure comprising a substrate inward terminal;
providing a dielectric structure over the seed and the substrate passivation layer;
removing a portion of the seed to expose a side of the substrate inward terminal, wherein the side of the substrate inward terminal is recessed from a side of the substrate passivation layer by a dishing height;
providing an electronic component comprising a component passivation layer over the substrate passivation layer, wherein the electronic component defines a void between the exposed side of the substrate inward terminal and a component interconnect of the electronic component;
coupling the substrate passivation layer to the component passivation layer along a bond boundary; and
bonding the substrate inward terminal to the component interconnect along the bond boundary by applying a bonding temperature.

10. The method of claim 9, wherein a metal of the component interconnect diffuses across the bond boundary in response to application of the bonding temperature.

11. The method of claim 9, wherein the bonding temperature is between 250° C. and 400° C.

12. The method of claim 9, wherein the dishing height is equal to a thickness of the removed portion of the seed.

13. The method of claim 9, wherein the dielectric structure comprises an organic material.

14. The method of claim 9, wherein the substrate inward terminal further comprises:
a barrier layer coupled to the conductive structure; and
an interface layer coupled to the barrier layer, the interface layer comprising a gold portion and a copper portion.

15. The method of claim 14, further comprising forming a gold-copper alloy from the gold portion and the copper portion by applying an alloying temperature.

16. An electronic device, comprising:
an electronic component comprising:
a component passivation layer coupled to the electronic component; and
a component interconnect extending from the electronic component through the component passivation layer, wherein a side of the component passivation layer and a side of the component interconnect are located along a bond boundary; and
a substrate coupled to the electronic component, the substrate comprising:
a substrate passivation layer coupled to the component passivation layer along the bond boundary, wherein the substrate passivation layer comprises inner walls defining an aperture;
a seed coupled to the inner walls of the substrate passivation layer;
an interface layer coupled to the component interconnect along the bond boundary and coupled to the seed;
a barrier layer coupled to the interface layer, wherein the interface layer is between the seed and the barrier layer;
a dielectric structure coupled to the substrate passivation layer; and
a conductive structure extending through the dielectric structure and into the aperture, wherein the conductive structure is coupled to the barrier layer.

17. The electronic device of claim 16, wherein the interface layer comprises a gold-copper alloy.

18. The electronic device of claim 17, wherein gold from the gold-copper alloy is diffused across the bond boundary.

19. The electronic device of claim 16, wherein a terminal end of the seed is spaced from the bond boundary.

20. The electronic device of claim 16, wherein the substrate passivation layer and the component passivation layer comprise an inorganic material, and wherein the dielectric structure of the substrate comprises an organic material.
